(19) United States
(12) Patent Application Publication
(10) Pub. No.: US 2026/0135491 A1
(43) Pub. Date: May 14, 2026

(54) CURRENT SENSING CIRCUIT

(71) Applicant: Renesas Design (UK) Limited, Bourne End (GB)

(72) Inventors: Yu RONG, San Jose, CA (US); Keyue SHAN, San Jose, CA (US); Kai-Wen CHIN, San Jose, CA (US); Guang FENG, San Jose, CA (US); Kranthi PAMARTHI, San Jose, CA (US)

(73) Assignee: Renesas Design (UK) Limited, Bourne End (GB)

(21) Appl. No.: 18/947,106

(22) Filed: Nov. 14, 2024

(51) Int. Cl. H02M 3/335; G01R 19/165; H02H 7/12; H02M 1/00; H02M 1/36

(52) U.S. Cl. CPC H02M 3/33576; G01R 19/16576; H02H 7/1213; H02M 1/0009; H02M 1/36; H02M 3/33571

(57) ABSTRACT

A converter circuit configured to operate over a plurality of switching cycles is provided. The converter circuit includes: a first switch controlled according to a first switching pattern; a second switch controlled according to a second switching pattern; a resonant circuit connected across the first switch; a current sensing circuit; and an integrated circuit. The integrated circuit includes a current sensing pin. The integrated circuit is configured to digitally control the first and second switching patterns. When the first switching pattern is set to off, the converter circuit is configured to: determine whether a first condition is met; determine whether a second condition is met; if it is determined that the first condition and the second condition are met, determine that the first switch is falsely turned on.

### FIELD

The present disclosure relates to overcurrent detection and protection for a current conversion circuit.

### BACKGROUND

For half bridge, HB, or full bridge, FB, converters, it is a known issue for high-side, HS, gate driver that there exists the risk that the HS gate may be falsely turned on by a high dv/dt spike coupled into the switching node (HB pin).

The HS gate driver is turned on/off by the pulse trigger. A high dv/dt spike coupled into the HB pin may go through an isolator (for example, a level shifter) and be coupled into a pulse trigger input. The high dv/dt spike is most likely to happen when a low-side, LS, switch turns off. Additionally, the higher the input voltage, the higher the risk of a high dv/dt spike. In comparison to the HS gate driver, the LS gate driver uses the voltage level to turn on or off, and therefore has much less chance to mis-trigger.

If HS gate is falsely turned on, it cannot be automatically turned off by itself. Since the HIN logic is OFF but the HO output is ON, there will be no turn off pulse (falling edge trigger) sent from the controller IC. As a result, HS gate will continuously stay on, leading to the power converter becoming damaged by overcurrent stress.

It is known that the risk of HS gate falsely on is due to the high dv/dt coupled into the switching node. A known example to deal with this issue is to add isolation between the HS and LS to attenuate noise coupling. However, the added isolation stage in the gate driver IC increases the IC cost as well as increasing gate signal propagation delay. Therefore, an alternative approach for HS gate falsely on protection is required to ensure converter safe operation without adding additional gate signal propagation delay.

Therefore, it is desirable to provide a mechanism to protect against the HS gate being falsely on.

### SUMMARY

According to a first aspect of the disclosure, there is provided a converter circuit configured to operate over a plurality of switching cycles, the converter circuit comprising: a first switch controlled according to a first switching pattern; a second switch controlled according to a second switching pattern; a resonant circuit connected across the first switch; and a current sensing circuit; an integrated circuit, IC, comprising a current sensing, CS, pin, wherein the IC is configured to control the first and second switching patterns; wherein, when the first switching pattern is set to off, the converter circuit is configured to: determine whether a first condition is met; determine whether a second condition is met; if it is determined that the first condition and the second condition are met, determine that the first switch is falsely turned on.

Optionally, wherein when it is determined that the first switch is falsely on, the converter circuit is configured to perform a protection function.

Optionally, wherein the protection function comprises: generating a first correction signal; and transmitting the first correction signal to the first switch to turn it off.

Optionally, wherein the protection function further comprises: if, after the correction signal is transmitted, the first condition and the second condition are still met, transmitting a further correction signal.

Optionally, wherein if it is determined that the first and second condition are still met after a predefined number of correction signals have been transmitted, the converter circuit is configured to: enter a fault protection mode, wherein the fault protection mode comprises shutting down and restarting the IC.

Optionally, wherein if the fault protection mode is triggered more than once in a predefined first time period, a next switching cycle will begin after a second predefined time period.

Optionally, wherein, when it is determined that the first condition and the second condition are met, the converter circuit is further configured to: determine whether the second switch is turned on; and if it is determined that the second switch is turned on, turn off the second switch.

Optionally, wherein the first condition is that the first switching pattern is set to off.

Optionally, wherein the second condition comprises that a first voltage exceeding a first threshold is detected across the CS pin.

Optionally, wherein the second condition further comprises that the first voltage exceeds the first threshold for a predefined third period of time.

Optionally, wherein the second condition is that a second voltage exceeding a second threshold is detected; wherein the second voltage is a voltage between the first switch and the second switch.

Optionally, wherein the second condition further comprises that the second voltage exceeds the second threshold for a predefined fourth period of time.

Optionally, wherein the first correction signal is an on signal transmitted to the first switch wherein the on signal is configured to end after a fifth period of time.

Optionally, wherein the resonant circuit comprises: an inductive device; or an inductive device and a capacitor.

Optionally, wherein the inductive device is an inductor or transformer.

According to a second aspect of the disclosure, there is provided a method of operating a converter circuit configured to operate over a plurality of switching cycles, the method comprising: controlling, by an integrated circuit, IC, the plurality of switching cycles for a first switch and a second switch; when the first switching pattern is set to off: determining whether a first condition is met; determining whether a second condition is met; if it is determined that the first condition and the second condition are met, determining that the first switch is falsely turned on.

### BRIEF DESCRIPTION OF THE DRAWINGS

The disclosure is described in further detail below by way of example and with reference to the accompanying drawings, in which:

FIG. 1 shows a block diagram representing a current sensing device;

FIG. 2 shows a circuit diagram with resonant tank on the low side;

FIG. 3 shows a circuit diagram with resonant tank on the high side;

FIG. 4 shows a diagram illustrating a switching pattern;

FIG. 5 shows a flowchart illustrating a method of operating a fault detection circuit;

FIG. 6 shows a flowchart illustrating a method of operating a fault detection circuit;

FIGS. 7A and 7B each show a flowchart illustrating a method of operating a fault detection circuit; and

FIG. 8 shows a diagram illustrating a switching pattern and circuit waveforms.

### DETAILED DESCRIPTION

The present disclosure relates to a novel HS gate falsely on protection mechanism which provides a way to detect an HS gate falsely on fault and protect the converter in a timely manner.

In the current disclosure, an “HS gate falsely on fault” refers to when a spike in voltage (for example, a spike in voltage associated with another function of the circuit) causes the high side, HS, gate to mistakenly turn on. That is, while a switching pattern controlling the high side and low side switches would have the HS gate (and thus the HS switch) set to off, the spike in voltage may cause the HS switch to turn on. This is a problem because the HS switch being on continuously in this situation causes damage to the circuit.

In the current disclosure, a “switching pattern” refers to a set of instructions for digitally controlling a set of switches over a period of time. An example switching pattern is shown in FIG. 4 and discussed in more detail in relation thereto. Each switch may be controlled according to a specific switching pattern. For example, the high side switch may be controlled according to a high side switching pattern and the low side switch may be controlled according to a low side switching pattern. It may be said that a switching pattern is “set to off” or “set to on” when the switching pattern would have the associated switch turned off or on, respectively.

In the current disclosure, “high side” refers to a power supply side of the bridge circuit; “low side” refers to a ground side of the bridge circuit.

In the current disclosure, “over current protection”, or “OCP”, refers to the implementation of any method used to detect a resonant overcurrent and protect against damage that the overcurrent might cause.

In the current disclosure, a “converter circuit” refers to a full-bridge or half-bridge power conversion circuit.

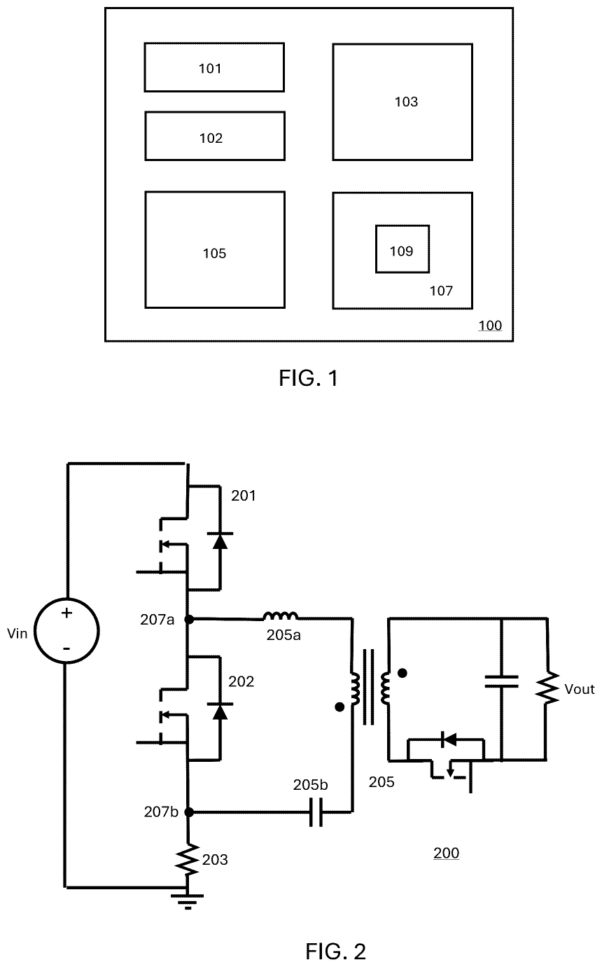

FIG. 1 is a block diagram representing a converter circuit 100 according to a first aspect of the disclosure. The converter circuit 100 comprises a first switch 101; a second switch 102; a resonant circuit 105; a current sensing circuit 103; and an integrated circuit 107, IC, comprising a current sensing, CS, pin 109.

The IC 107 is configured to digitally control the first 101 and second 102 switch according to first and second switching patterns, respectively.

The first and second switches 101, 102 may be any kind of switching device. For example, the first and second switches 101, 102 may be a MOSFET, GaN, IGBT or any other such device. The first and second switches 101, 102 may be the same type of device or may be different types of devices.

The current sensing circuit 103 may be any kind of resistive device or current sensor. For example, the current sensing circuit 103 may be a sensor resistor.

The resonant circuit 105 (or resonant tank) may comprise an inductor, transformer, and/or capacitor. In more detail, the resonant circuit 105 may comprise an inductive device (which may be an inductor and/or a transformer) and a capacitor. Alternative the resonant circuit 105 may comprise only an inductive device (which may be an inductor and/or a transformer).

FIG. 2 shows a converter circuit (in this example, it is shown as a half bridge converter circuit, but it should be known that it may also be a full bridge converter circuit), wherein a resonant circuit is connected on a low side of the converter circuit such that the inductor 205 is connected between a first (or high side, HS) switch 201 and a second (low side, LS) switch 202. The converter circuit of FIG. 2 may be a converter circuit according to the circuit represented by FIG. 1.

The converter circuit 200 may be a half bridge converter circuit (as shown) or may be a full bridge converter circuit. The converter circuit 200 is configured such that a resonant circuit 205 is connected on a low side of the converter circuit such that the inductor 205a of the resonant circuit 205 is connected between the first switch 201 (or high side switch) and the second switch 202 (or low side switch) at node 207a and a capacitor 205b of the resonant circuit 205 is connected between the second switch 202 and a current sensing circuit 203 at node 207b. A current sensing, CS, pin 209 of an integrated circuit, IC, is coupled to the node 207b.

In this example, if the first switch 201 is falsely on (for example, if it were turned on by a voltage spike when the switching pattern for the HS switch 201 is set to off) when the LS switch 202 turns on, a shoot through current is caused between the HS and LS switches. Thus, a large current flows through the current sensing circuit 203 leading to the activation of OCP. Additionally, if the HS gate is falsely on when the LS switch turns off, current will also flow through the current sensing circuit 203, which also leads to the activation of OCP.

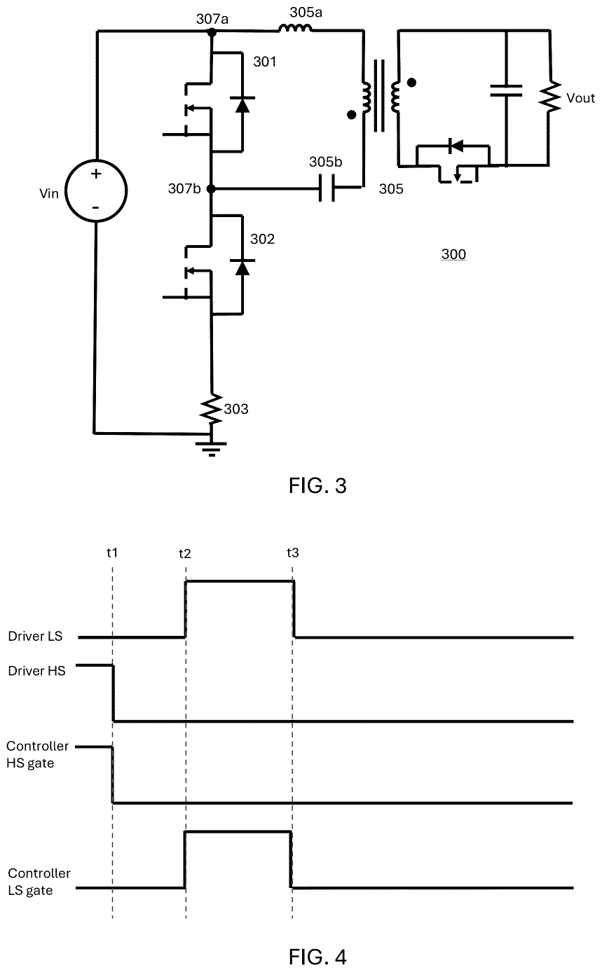

FIG. 3 shows a converter circuit 300 (in this example, it is shown as a half bridge converter circuit, but it should be known that it may also be a full bridge converter circuit). The converter circuit of FIG. 3 may be a converter circuit according to the circuit represented by FIG. 1.

The converter circuit 300 may be a half bridge converter circuit (as shown) or may be a full bridge converter circuit. The converter circuit 300 is configured such that a resonant circuit 305 is connected on a high side of the converter circuit such that the inductor 305a of the resonant circuit 305 is connected above a first switch 301 (or high side switch) at node 307a and a capacitor 305b of the resonant circuit 305 is connected between the first switch 301 and a second switch 302 (or low side switch) at node 307b (also known as a “switching node”). A current sensing, CS, pin 309 of an integrated circuit, IC, is coupled between the second switch 302 and the current sensing circuit 303.

In this example, if the first switch 301 is falsely on (for example, if it were turned on by a voltage spike when the switching pattern for the first switch 301 is set to off) when the second switch 302 turns on, a shoot through current will be caused to flow through the first and second switches 301, 302. This shoot through current is detected by the current sensing circuit 303, allowing OCP to be triggered. If the first switch 301 is falsely on when the second switch 302 turns off, in this configuration, no current flows through the current sensing circuit 303 and thus the current sensing circuit 303 cannot be used for OCP fault detection. In this case, the node 307a may be used for first switch falsely on protection, by detecting a voltage across the node 307a ; when the voltage across the node 307a is increased to Vin (the input voltage of the circuit), falsely on protection may be triggered.

It can be seen that a way to detect when the first switch 201, 301 is falsely on is desirable, as will now be discussed.

The converter circuit 200, 300 is configured to operate over a plurality of switching cycles and comprises the first switch 201, 301 controlled according to a first switching pattern; the second switch 202, 302 controlled according to a second switching pattern; a resonant circuit 205, 305 connected across the first switch 201, 301; a current sensing circuit 203, 303; and an integrated circuit, IC, comprising a current sensing, CS, pin 209, 309, wherein the IC is configured to control the first and second switching patterns; wherein, when the first switching pattern is set to off, the converter circuit 200, 300 is configured to: determine whether a first condition is met; determine whether a second condition is met; and, if it determined that the first condition and the second condition are met, determine that the first switch is falsely on.

That is, when the first switching pattern is set to off (meaning that the first switch 201, 301 should be turned off), it is determined whether the first condition and the second condition are met and, if both conditions are met, it is determined that the first switch is falsely on despite the first switching pattern being set to off (thus, an error has occurred and the control by the IC has been superseded). Control by the IC may be digital or analog.

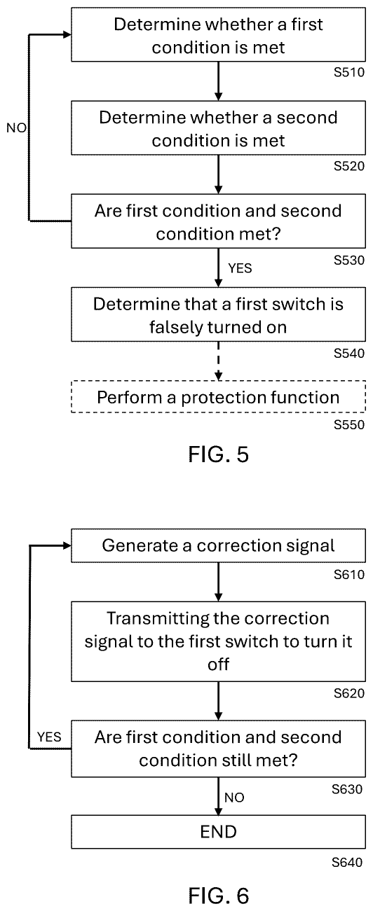

FIG. 5 is a flowchart representing a method of operating a converter circuit (for example, the converter circuits of any of FIGS. 1-3, half bridge or full bridge). FIG. 5 relates to a fault detection mechanism of the converter circuit, in particular detecting when the first switch 201, 301 is falsely on.

In Step S510, it is determined whether a first condition is met.

The first condition may be that the first switching pattern is set to off. That is, no control signal has been transmitted by the IC to control the first switch 201, 301 to turn on.

In step S520, it is determined whether a second condition is met.

In a first example, the second condition may be that a first voltage exceeding a first threshold is detected across the CS pin 209, 309 of the IC. Additionally, the second condition may require that the first voltage exceeds the first threshold for a predefined period of time. For example, the second condition may be that a first voltage exceeding a first threshold is detected across the CS pin 209, 309 of the IC when the converter circuit is configured such that the resonant circuit 205, 305 is connected to the low side of the circuit.

Alternatively, in a second example, the second condition may be that a second voltage exceeding a second threshold is detected, wherein the second voltage is a voltage between the first switch and the second switch. Additionally, the second condition may require that the second voltage exceeds the second threshold for a predefined period of time. For example, the second condition may be that a second voltage exceeding a second threshold is detected, wherein the second voltage is a voltage between the first switch and the second switch, when the converter circuit is configured such that the resonant circuit 205, 305 is connected to the high side of the circuit. In this case, no current will flow through the current sensing circuit 203, 303 when the second switch 202, 302 turns on and thus the CS pin 209, 309 cannot be used to detect the fault and a voltage across node 307b must be detected instead.

In step S530, it is determined whether both the first condition and the second condition are met.

In step S540, if it is determined that both the first and second conditions are met, it is determined that the first switch 201, 301 is falsely on.

If it is determined that both the first and second conditions are not met, the method begins again at step S510.

Optionally, in step S550, a protection function may be performed.

An example switching pattern is shown in FIG. 4. This diagram shows lines representing on/off patterns for four signal lines. The first signal is a low-side driver signal, the second signal is a high-side driver signal, the third signal is a control signal for the first switch 201, 301, and the fourth signal is a control signal for the second switch 202, 302.

It can be seen at a first time, t1, that the third signal turns off, meaning that the first switch 201, 301 is turned off. Then, at a second time, t2, the first and fourth signals turn on, thus turning on the second switch 202, 303. Finally, at a third time, t3, the first and fourth signals turn off, thus turning off the second switch 202, 302. This is an example of a switching cycle.

When the first switch 201, 301 is falsely on, the second signal will be on while the third signal is off because although the first switch 201, 301 is on, no digital control signal has been transmitted by the IC.

Thus, when it is determined that the first switch is falsely on, the converter circuit 200, 300 is configured to perform a protection function.

FIG. 6 is a flowchart illustrating a method of operating a converter circuit. FIG. 6 relates specifically to the protection function. The protection function may be part of the method discussed by reference to FIG. 5, relating to the converter circuits discussed by reference to FIGS. 1-3. FIG. 6 relates to a fault correction mechanism of the converter circuit, in particular correcting when the first switch 201, 301 is falsely on.

In step S610, a correction signal is generated. In step S620, the generated correction signal is transmitted to the first switch 201, 301 to turn it off.

The correction signal may be an on signal transmitted to the first switch 201, 301, wherein the on signal is configured to end after a period of time. In more detail, if the HS gate falsely on protection is triggered (when both the first condition and the second condition are met), the first switch 201, 301 is forced to turn off. This may be done by transmitting a correction signal to the first switch 201, 301, wherein the correction signal is an ad hoc on signal that is transmitted outside of the usual first switching pattern for the first switch 201, 301. The correction signal may be considered to be a pulse, wherein the on signal is maintained for short period of time before stopping and thus turning off the first switch 201, 301. For example, the on signal may be maintained for between 100 ns and 200 ns. In comparison, an on signal during normal operation may be of micro-second duration, rather than the nano-second duration of the correction signal.

In step S630, it is determined whether the first condition and the second condition are still met.

That is, it is determined whether both conditions remain met. For example, it is determined whether both the first switching pattern is set to off and whether either the first voltage exceeds the first threshold or the second voltage exceeds the second threshold.

If it is determined that both conditions remain met, a further correction signal may be generated and transmitted to the first switch 201, 301. That is, the steps of FIG. 6 may be repeated. It may be the case that the steps of FIG. 6 are repeated a plurality of times.

It may be the case that step S630 does happen immediately after step S620. Rather, it may be the case that step S630 happens a predefined period of time after step S620. This may ensure that a further correction signal is not transmitted in error.

In some cases, it is possible that the steps of FIG. 6 are repeated many times within a certain period of time. This may indicate that the fault in the circuit is not being fixed by the correction signal. In this case, a fault protection mode may be entered.

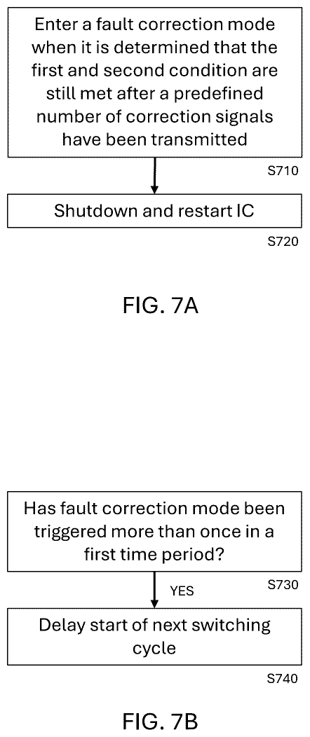

FIGS. 7A and 7B are a flowcharts illustrating methods of operating a converter circuit. FIGS. 7A and 7B relate specifically to a fault protection mode. The fault protection mode may be part of the method discussed by reference to FIGS. 5 and 6, relating to the converter circuits discussed by reference to FIGS. 1-3. FIG. 7A relates to a fault protection mechanism of the converter circuit, in particular detecting when multiple correction signals have been transmitted. FIG. 7B relates to a fault protection mechanism of the converter circuit, in particular detecting when a fault is repeatedly triggered.

If, after sending out several consecutive correction signals, the fault is still triggered (and therefore both conditions remain met), it is likely that the first switch driver is damaged and thus may no longer be able to turn off the first switch 201, 301 anymore. This causes the fault protection mode to trigger, which leads the IC to shut down and restart. This is discussed in more detail in steps S710 and S720, with reference to FIG. 7A.

In step S710, when it is determined that the first and second conditions are still met after a predefined number of correction signals have been transmitted, the converter circuit may be configured to enter a fault protection mode.

In step S720, the IC may be controlled to shut down and restart.

FIG. 7B is a flowchart which relates to when it is determined that the fault protection mode has been triggered multiple times in a predefined period, indicating that there is a persistent fault. This is discussed in more detail in steps S730 and S740, with reference to FIG. 7B.

In step S730, it may be determined whether the fault protection mode has been triggered more than once in a predefined time period. For example, the predefined time period may be a time period with a length in the milli-second range.

For example, if within a predefined time period the fault protection mode is triggered for a second time, the fault protection mode may be triggered.

Alternatively, the fault protection mode may be triggered more than once in the predefined time period. In this case, there may be a predefined threshold number of times that fault protection mode may be triggered and it may be determined whether a number of times the fault protection mode has been triggered exceeds the threshold.

In step S740, if it is determined that the fault protection mode has been triggered more than once in the predefined time period, the start of the next switching cycle may be delayed.

That is, the IC may delay the start of the next switching cycle. For example, the IC may only start the switching cycle after a predefined period of time. The predefined period of time may be in the range of micro-seconds. For example, the delay may be 100 us or longer.

Alternatively, the fault protection mode may be triggered more than once in the predefined time period. In this case, if it is determined that the fault protection mode has been triggered a number of times exceeding the threshold, the start of the next switching cycle may be delayed.

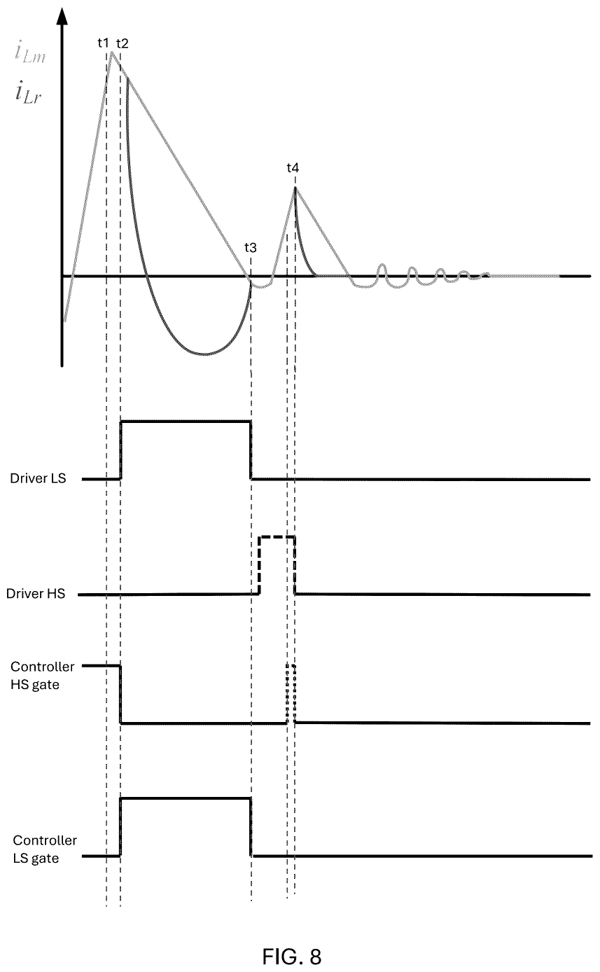

FIG. 8 is a diagram illustrating an example of the method of operating a converter circuit being implemented. The method may be the method discussed by reference to FIGS. 5 and 6, relating to the converter circuits discussed by reference to FIGS. 1-3.

FIG. 8 shows a graph illustrating the current values of the inductor circuit during a single switching cycle wherein the first switch 201, 301 turns on falsely. The graph is compared with a signal diagram illustrating the various signals (such as those discussed by reference to FIG. 4) throughout the switching cycle.

At time t1, a spike in current as the second switch 202, 302 turns on can be seen. This may cause a resonant current, as shown by the line labelled iLR.

At time t2, the second switch 202, 302 turns on, as can be seen in the first signal labelled “Driver LS” and the fourth signal labelled “Controller LS Gate”, wherein the first signal is a signal of the second switch 202, 302 itself and the second signal is the control signal transmitted by the IC to the second switch 202, 302 to control it to turn on.

Shortly after t2, the third signal labelled “Driver HS”, which is a signal of the first switch 201, 301 turns on. This corresponds to the first switch 201, 301 falsely turning on. It can be seen that there is no corresponding switch on of the third signal labelled “Controller HS Gate” which corresponds to the control signal transmitted by the IC to the first switch 201, 301.

At time t3, the false on signal has been detected, as per the method described by reference to FIG. 5, and a correction pulse is generated and transmitted. This is shown in the third signal.

At time t4, the correction signal has been received by the first switch 201, 301 and it turns off when the correction signal ends.

Thus, it can be seen that the current disclosure provides a method of detecting and protecting against a high side switch (such as the first switch 201, 301) turning on when digital control for the high side switch is off (thus, when the high side switch is falsely on). Once a fault is detected, a correction signal is generated and transmitted to turn off the high side switch. If the fault continues to trigger, further correction signals may be transmitted and, if the fault still continues, the IC may be shut down and restarted.

Various improvements and modifications can be made to the above without departing from the scope of the disclosure.

1. A converter circuit configured to operate over a plurality of switching cycles, the converter circuit comprising:
a first switch controlled according to a first switching pattern;
a second switch controlled according to a second switching pattern;
a resonant circuit connected across the first switch;
a current sensing circuit; and
an integrated circuit (IC), comprising a current sensing (CS) pin, wherein the IC is configured to control the first and second switching patterns;
wherein, when the first switching pattern is set to off, the converter circuit is configured to:
determine whether a first condition is met;
determine whether a second condition is met; and
if it is determined that the first condition and the second condition are met, determine that the first switch is falsely turned on.

2. The converter circuit of claim 1, wherein when it is determined that the first switch is falsely on, the converter circuit is configured to perform a protection function.

3. The converter circuit of claim 2, wherein the protection function comprises:
generating a first correction signal; and
transmitting the first correction signal to the first switch to turn it off.

4. The converter circuit of claim 3, wherein the protection function further comprises:
if, after the correction signal is transmitted, the first condition and the second condition are still met, transmitting a further correction signal.

5. The converter circuit of claim 4, wherein if it is determined that the first and second condition are still met after a predefined number of correction signals have been transmitted, the converter circuit is configured to:
enter a fault protection mode, wherein the fault protection mode comprises shutting down and restarting the IC.

6. The converter circuit of claim 5, wherein if the fault protection mode is triggered more than once in a predefined first time period, a next switching cycle will begin after a second predefined time period.

7. The converter circuit of claim 1, wherein, when it is determined that the first condition and the second condition are met, the converter circuit is further configured to:
determine whether the second switch is turned on; and
if it is determined that the second switch is turned on, turn off the second switch.

8. The converter circuit of claim 1, wherein the first condition is that the first switching pattern is set to off.

9. The converter circuit of claim 1, wherein the second condition comprises that a first voltage exceeding a first threshold is detected across the CS pin.

10. The converter circuit of claim 9, wherein the second condition further comprises that the first voltage exceeds the first threshold for a predefined third period of time.

11. The converter circuit of claim 1, wherein the second condition is that a second voltage exceeding a second threshold is detected;
wherein the second voltage is a voltage between the first switch and the second switch.

12. The converter circuit of claim 11, wherein the second condition further comprises that the second voltage exceeds the second threshold for a predefined fourth period of time.

13. The converter circuit of claim 3, wherein the first correction signal is an on signal transmitted to the first switch wherein the on signal is configured to end after a fifth period of time.

14. The converter circuit of claim 1, wherein the resonant circuit comprises:
an inductive device; or
an inductive device and a capacitor.

15. The converter circuit of claim 14, wherein the inductive device is an inductor or transformer.

16. A method of operating a converter circuit configured to operate over a plurality of switching cycles, the method comprising:
controlling, by an integrated circuit, IC, the plurality of switching cycles for a first switch and a second switch;
when the first switching pattern is set to off:
determining whether a first condition is met;
determining whether a second condition is met; and
if it is determined that the first condition and the second condition are met, determining that the first switch is falsely turned on.
